(19) United States
(12) Patent Application Publication
(10) Pub. No.: US 2011/0269307 A1
(43) Pub. Date: Nov. 3, 2011

(54) Method for Making Integrated Circuit Device Using Copper Metallization on 1-3 PZT Composite

(75) Inventors: Yakub Aliyu, Palm Beach Gardens, FL (US); Deda Diatezua, Wellington, FL (US)

(73) Assignee: Sonavation, Inc., Palm Beach Gardens, FL (US)

(21) Appl. No.: 13/098,964

(22) Filed: May 2, 2011

Related U.S. Application Data
(60) Provisional application No. 61/329,605, filed on Apr. 30, 2010.

(51) Int. Cl. H01L 21/768

(52) U.S. Cl. 438/622; 257/E21.575

(57) ABSTRACT

Provided herein is a method of making an integrated circuit device using copper metallization on 1-3 PZT composite. The method includes providing an overlay of electroplated immersion of gold (Au) to cover copper metal traces, the overlay preventing oxidation on 1:3 PZT composite with material. Also included is the formation of immersion Au nickel electrodes on the 1-3 PZT composite to achieve pad metallization for external connections.

### CROSS-REFERENCE TO RELATED APPLICATIONS

This application claims benefit to U.S. Provisional Application No. 61/329,605, filed on Apr. 30, 2010, which is incorporated herein by reference.

### BACKGROUND OF THE INVENTION

1. Field of the Invention

The present invention is generally directed to integrated circuit (IC) fabrication on 1-3 PZT Composite Material.

2. Background Art

Traditional techniques for manufacturing ICs include the use of copper. Copper

(Cu) is often used to form the metal trace interconnects used in these ICs. Copper is highly desirable because of its high conductivity (i.e., lower resistivity). The resistivity of copper is 1.7 μΩcm compared to 2.2 μΩcm for gold (Au) and 2.7 μΩcm for aluminum (Al). Its conductivity makes it the second best conductor metal, second only to silver (Ag). Silver, however, is not particularly useful for interconnection applications for ICs due to its excessive aggressiveness to diffusion in most dielectrics.

Additionally, copper is relatively inexpensive compared to gold (Au) and has several characteristics that make it well suited for use in the fabrication process of device manufacturing. It's excellent material properties ensure increased reliability and device performances.

Copper, however, is subject to rapid oxidation. Copper oxidation, forming copper oxide (CuO or CuO₂), is due to its inherent high chemical reactivity when exposed to oxygen. This rapid oxidation represents a significant challenge in manufacturing ICs. Passivation of Cu surface for oxidation prevention becomes then unavoidable. Usually an extra fine layer of Au is deposited on top of Cu for that purpose. Au immersion is generally the technology of choice to coat the Cu surface. After deposition of the Au layer on top of Cu, both materials diffuse into each other quasi instantaneously across several monolayers, forming a CuₓAu₁₋ₓ alloy thin layer which is as good a conductor as Cu and Au. This thin layer presents very high resistance to corrosion compared to bare copper, becoming de facto an oxidation barrier for an inner Cu layer.

An alternative dry process can be used to achieve Cu surface passivation. Low rate oxidation layer such as NiV does provide very good passivation for Cu. NiV is deposited on top of Cu in-situ using PVD (sputtering) technique to prevent any exposition to atmosphere to Cu surface.

One of the specific challenges of the copper oxidation process is the formation of insulating copper oxides on the surface. Copper oxide is an insulator. Thus, its progressive formation over time will reduce the effective cross-section of the interconnect line. This formation will also lead to a steady degradation of the line's resistance (i.e., increasing resistance) to the flow of current, ultimately contributing to poor device performance.

The oxide is also very brittle. Its brittle nature weakens the overall metal line, making it more susceptible to thermo-compression stresses during assembly. This brittleness also creates vulnerabilities to other mechanical stresses that the line will likely experience during normal device utilization. In other words, corrosion of the metal trace will cause long term performance and reliability issues.

What is needed, therefore, are methods and systems to overcome the aforementioned deficiencies related to using copper in IC manufacturing and fabrication on 1-3 PZT Composite material.

### BRIEF SUMMARY OF EMBODIMENTS OF THE INVENTION

The present invention meets the above-described needs by providing a method of making an integrated circuit device using copper metallization on 1-3 PZT composite. The method includes providing an overlay of electroplated immersion of gold (Au) to cover copper metal traces, the overlay preventing oxidation on 1:3 PZT composite with material. Also included is the formation of immersion Au nickel electrodes on 1-3 PZT composite to achieve pad metallization used for external connections.

Another embodiment provides a method of using low resistivity and high conductivity metallization for achieving an IC on a 1:3 PZT composite. This includes achieving low cost copper metallization to fabricate a device 1-3 PZT Composite.

In yet another embodiment, a technique is provided for using a reverse mask litho and sacrificial photo resist to define electrical connections without affecting the device active circuit area. This technique helps to provide nickel pads with an immersion Au coating. The coating is useful in achieving high performance and creating reliable connections to the external circuits required during the bonding process.

The bonding process is traditionally challenging due to the non-homogeneous nature of the 1-3 PZT composite surface. This non-homogeneity can be problematic due the lack of rigidity required in conventional thermo compression bonding techniques. Embodiments of the present invention offer solutions to these challenges.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present invention and, together with the description, further serve to explain the principles of the invention and to enable a person skilled in the relevant art(s) to make and use the invention.

FIG. 1 is an illustration of an exemplary sensor metal stack constructed in accordance with an embodiment of the present invention.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### DETAILED DESCRIPTION OF EMBODIMENTS OF THE INVENTION

Embodiments of the present invention provide methods and systems related to integrated circuit (IC) fabrication on 1-3 PZT composite material. In the detailed description that follows, references to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

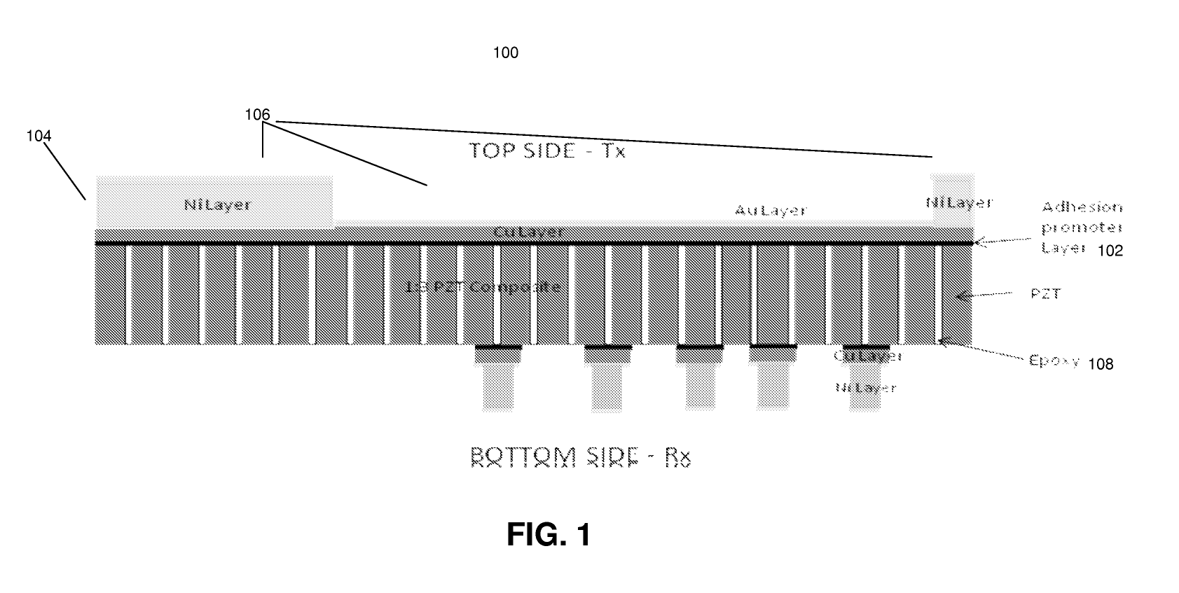

FIG. 1 is an illustration of an exemplary copper metallization stack 100 on 1-3 PZT composite material 102 in accordance with an embodiment of the present invention. The stack 100 can be used to makes devices that sense biometric data, such as finger prints. In FIG. 1, an exemplary method is shown for making an IC onto a 1:3 PZT composite that substantially prevents copper oxidation during the manufacture of the device. This method can be useful, for example, in the manufacture of devices used as sensors or used in medical applications.

The stack 100 illustrates lithography patterning with photoresist on a top side Tx and a bottom side Rx, with plasma ashing of a 1:3 PZT composite surface. Also shown is a sputtering 20−100 nm adhesion promoter layer 102.

A sputtering 1.5−3 μm thick copper layer 104 is also provided, along with liftoff, to uncover defined copper line patterns. Also shown is lithography to protect pad areas, active copper etching for Cu oxide removal, coat exposed Cu traces with 20−80 nm thick gold for oxidation protection, and lithography to protect Au coated trace areas 106, exposing only Cu pad areas. Active copper etching for Cu oxide removal at pad areas is shown, along with Pd activation, active chemical rinse to remove non reduced palladium across the surface, and Ni electroless plating of pad areas. An epoxy 108 serves to create the special substrate 1:3 PZT composite material. The epoxy 108 is a polymer material that glues and maintain all the piezo-electric ceramic pillars in a network together.

In the stack 100 of FIG. 1, the 1-3 PZT composite is cleaned and the surface is treated under oxygen atmosphere plasma for between 2 and 15 minutes (0.1 to 2 KW). This step is used as a surface preparation technique in order to promote adhesion of a Ti (Titanium) promoter layer (50 to 100 nm) 102. The adhesion promoter layer 102 helps copper attach and adhere to the surface of the 1:3 PZT composite surfaces. This is an important requirement because of the surface roughness and non-homogeneity of the 1:3 PZT composite substrate, making adhesion very difficult.

As noted above, the adhesion promoter layer 102 facilitates the adherence of the next subsequent metal or material during the fabrication process (device manufacturing process). It is desirable that this layer 102 be very thin such that it is substantially invisible electrically for top to bottom electrical current direction. In other words, it should be sufficiently thin such that no consequential drop of voltage across it is noticeable.

Copper metal is sputtered upon and lift-off process is used to pattern the traces making the IC using standard photolithographic processes. These traces have a thickness between 0.5 um to 3.0 um. A masking layer is used to protect the conducting pad areas required for external connections. Chemical etching is used to remove copper native oxidation layer built up in the exposed active circuit area.

For long term protection of copper against oxidation, a thin immersion gold (Au) film layer 25 to 100 nm thick is plated on the Cu traces using electro less plating process technique, also-known-as Au-immersion. A photo resist pattern is used to mask the Au immersed circuit area leaving only pads areas exposed. This is followed by a plasma treatment for between 2 and 15 minutes (0.1 to 2 KW).

A reverse photo mask is used to expose only parts of the circuit destined to pads.

A palladium base solution is used to activate the Cu layer. An aggressive etchant is used to clean the surface prior to surface activation using immersion in palladium (Pd) based solution.

Two palladium monolayers)(Pd⁰ are formed on top of the Cu layer. An active chemical rinse is required to remove non reduced palladium ions (Pd²⁺) across the surface prior to nickel (Ni) electroless plating on the pad areas. The Nickel thickness is between 1 and 15 μm. The Nickel Pads are also protected against oxidation by a gold layer 20 nm and 80 nm thick deposited by immersion plating.

### CONCLUSION

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

What is claimed is:

1. A method of making an integrated circuit (IC) device using copper metallization on 1-3 PZT composite, comprising:
providing an overlay of electroplated immersion gold (Au) to cover copper metal traces, the providing preventing oxidation on the 1:3 PZT composite with material; and
forming an immersion of Au nickel electrodes on the 1-3 PZT composite to provide pad metallization for external connections of the IC.

2. A method of claim 1 where the immersion gold (Au) is replaced by sputtered Nickel Vanadium (NiV).
